(19) United States
(12) Patent Application Publication
(10) Pub. No.: US 2003/0016041 A1
(43) Pub. Date: Jan. 23, 2003

(54) Method and apparatus for testing semiconductor integrated circuit, and semiconductor integrated circuit manufactured thereby

(75) Inventors: Kiyotoshi Ueda, Tokyo (JP); Shoichi Ooshita, Tokyo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 09/766,845

(22) Filed: Jan. 23, 2001

(30) Foreign Application Priority Data
Jul. 17, 2000 (JP) 2000-216321

(51) Int. Cl. G01R 31/02

(52) U.S. Cl. 324/763

(57) ABSTRACT

A semiconductor integrated circuit testing apparatus of the invention comprises a correcting means for correcting input waveform timing of a measuring signal applied to all pins of a semiconductor integrated circuit 5. The correcting means includes: a high-speed clock generating circuit 12 for generating a clock signal; latch circuits 9a, 9b for latching the measuring signal by use of the clock signal from the high-speed clock generating circuit 12; FIFO memories 10a, 10b for storing as data the measuring signal latched by the latch circuits 9a, 9b; and a control circuit 14 for retrieving the data from the FIFO memories 10a, 10b for transfer to a tester.

### BACKGROUND OF THE INVENTION

1. Field of the Invention

The present invention relates to a method and an apparatus for testing semiconductor integrated circuits. More particularly, the present invention relates to a method for correcting, in an automated and a highly accurate manner, the timing of input waveforms supplied from a semiconductor testing device to input terminals of a semiconductor integrated circuit under functional test.

2. Background Art

In recent years, semiconductor integrated circuits (ICs) have seen their functionality advanced phenomenally, their operating frequencies raised to 250 MHz or higher and their number of pins greater than 1,000. Functional tests to which ICs are subjected require exacting tolerances of timing accuracy, five percent or less of the operating frequency, for input waveforms of various signals (within ±100 pS required during operation at 300 MHz).

The timing accuracy is expressed in terms of data input set-up time and hold time with regard to the clock input to ICs. There usually exist a plurality of pins for data input with respect to a clock input pin.

Furthermore, the timing accuracy has become subject to assurances not at external leads (or balls) of IC packages but at IC pads inside the IC package.

Semiconductor device testing apparatuses (called testers hereunder) for testing such ICs have also improved in operating frequency and pin count. Of such testers, those that meet IC requirements including timing accuracy are still very expensive today, and they are not ready to address assurances at chip pads inside the IC package.

Traditionally, the tester assures timing accuracy in two ways: calibration within the tester, and calibration of a dedicated test board fabricated for each IC.

Calibration inside the tester is carried out by equipment manufacturers using their proprietary hardware structure. Calibration of the test board, on the other hand, is most often conducted by use of a TDR (time domain reflectometer) technique. In the latter case, the signal transmission line needs to be left open or terminated. When terminated, the line is generally arranged to have an impedance of 50 ohms.

The TDR technique usually provides accuracy levels of only up to around 100 pS. For that reason, an actual test board is calibrated with concurrent use of an oscilloscope or like equipment allowing external observation of waveforms.

Under these circumstances, conventional methods for testing semiconductor integrated circuits have the following major disadvantages:

When probes of an oscilloscope are applied in contacting relation to the object under test, it is difficult repeatedly to obtain accurate waveforms regarding the target object. Where the number of signals exceeds 1,000 represented by as many pins, it takes such an inordinately long time to carry out the test that the testing procedure is becoming impractical.

The oscilloscope, if employed, is incapable of probing when it comes to calibrating IC pads inside the IC package.

Where TDR measurement is carried out on the IC package, I/O terminals of the IC vary so much in terms of impedance that there can be no impedance matching over signal paths between the tester and the test board. This makes it impossible to obtain reflected waveforms normally, which in turn makes electrical length measurement unachievable.

It is therefore an object of the present invention to overcome the above and other deficiencies of the prior art and to provide a method and an apparatus for calibrating with high precision the electric length from an input waveform source to IC pads of a semiconductor integrated circuit under functional test. It is also another object of the present invention to provide a semiconductor integrated circuit fabricated through the use of such a method and an apparatus.

### SUMMARY OF THE INVENTION

According to one aspect of the present invention, in a semiconductor integrated circuit testing method, a tester is caused to generate a measuring signal to all pins of a semiconductor integrated circuit, and a trigger signal is generated. The measuring signal is latched by use of the trigger signal. The latched measuring signal is stored as data into storing means. The stored data is reading from the storing means for output to the tester.

In another aspect, in the testing method, the data stored into the storing means represent electric lengths of all pins of the semiconductor integrated circuit.

In another aspect, in the testing method, a calibration data file is created based on the data sent to the tester.

In another aspect, in the testing method, the calibration data file is referenced to correct waveform timing of the measuring signal upon functional test performed by the tester.

According to another aspect of the present invention, a semiconductor integrated circuit testing apparatus comprises correcting means for correcting input waveform timing of a measuring signal applied to all pins of a semiconductor integrated circuit.

Other features and advantages of the invention will be apparent from the following description taken in connection with the accompanying drawings.

### BRIEF DESCRIPTION OF THE DRAWINGS

FIG. 1 is a block diagram of a tester and a test board;

FIG. 2 is a cross-sectional view of the setup shown in FIG. 1;

FIG. 3 is an explanatory view depicting how the length of signal wiring is obtained by the TDR technique;

FIG. 4 is a block diagram of a first embodiment of this invention;

FIG. 5 is a timing chart in effect when automatic calibration is performed;

FIG. 6 is a flowchart of steps outlining the technique of automatic calibration;

FIG. 7 is a block diagram showing key portions of a second embodiment of this invention; and

FIG. 8 is a timing chart in effect when the second embodiment of FIG. 7 operates.

### DETAILED DESCRIPTION OF THE PREFERRED EMBODIMENTS

Preferred embodiments of this invention will now be described with reference to the accompanying drawings.

First Embodiment

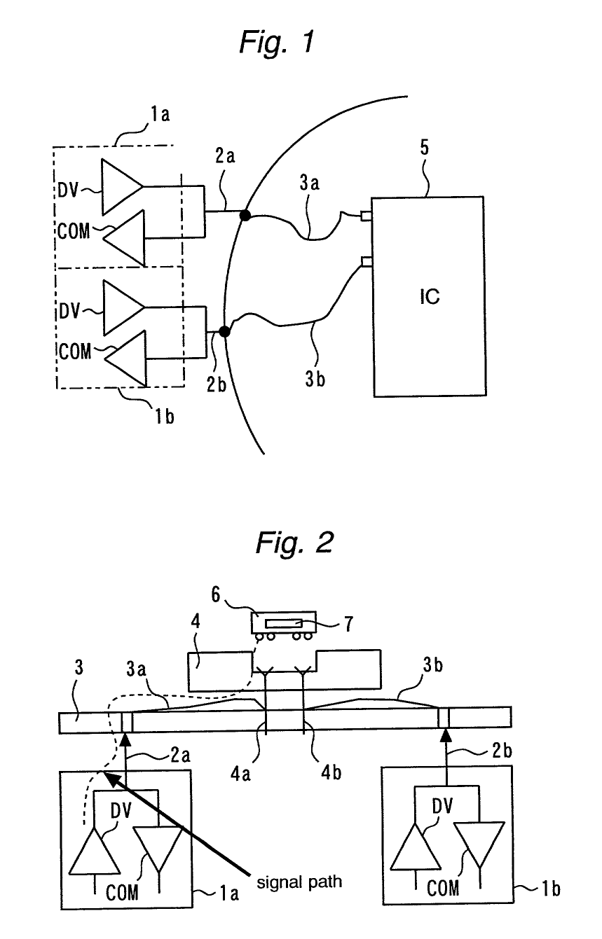

The operating principle of this invention is explained below by referring to FIGS. 1 through 3.

FIG. 1 is a block diagram of a tester and a test board. In FIG. 1, reference numerals 1a, 1b denote pin electronics parts each comprising a driver DV and a comparator COM for applying various signal waveforms to an IC, to be described later. Reference numerals 2a, 2b represent POGO pins for electrical contact with the test board. Numerals 3a, 3b stand for signal wiring on the test board, and numeral 5 denotes a device under test (semiconductor integrated circuit, called the IC hereunder) mounted on an IC socket, not shown.

FIG. 2 is a cross-sectional view of the setup in FIG. 1. In FIG. 2, the components having the same or corresponding functions as their counterparts in FIG. 1 are designated by like reference numerals, and their descriptions are omitted where redundant.

In FIG. 2, reference numeral 3 stands for the test board; 4 for an IC socket; 4a for a conductive probe embedded in the IC socket 4; 6 for an IC packet; and 7 for a semiconductor chip contained in the IC package 6. The IC package 6 and semiconductor chip 7 effectively constitute the IC 5 indicated in FIG. 1.

Various signal waveforms generated by the tester move from the pin electronics part 1a through the POGO pin 2a, signal wiring 3a on the test board 3, and probe 4a of the IC socket 4 to reach leads (or balls) of the IC package 6 before being ultimately sent to the semiconductor chip 7. The pin electronics part 1b, POGO pin 2b and signal wiring 3b constitute another stream that is likewise traveled by signal waveforms reaching leads (balls) of the IC package 6 via the probe 4b of the IC socket 4 before being eventually fed to the semiconductor chip 7.

Where the number of pins on the IC 5 exceeds 1,000, the signal wiring 3a, 3b on the test board 3 is too densely laid out to ensure equal electric lengths during fabrication. On the above setup, timing correction (called calibration hereunder) is first carried out as far as the end of the POGO pin 2a (FIG. 2) that is independent of the test board 3 under test.

The calibration procedure above, varying somewhat from one tester manufacturer to another, basically involves initially adjusting the voltage amplitude of each signal waveform and then checking the amount of divergences of waveform edges (skew values) relative to the reference signal. After the checked divergences are written as a calibration data file to a memory inside the tester, signal wiring lengths are corrected on the test board 3. This is where the TDR technique is utilized.

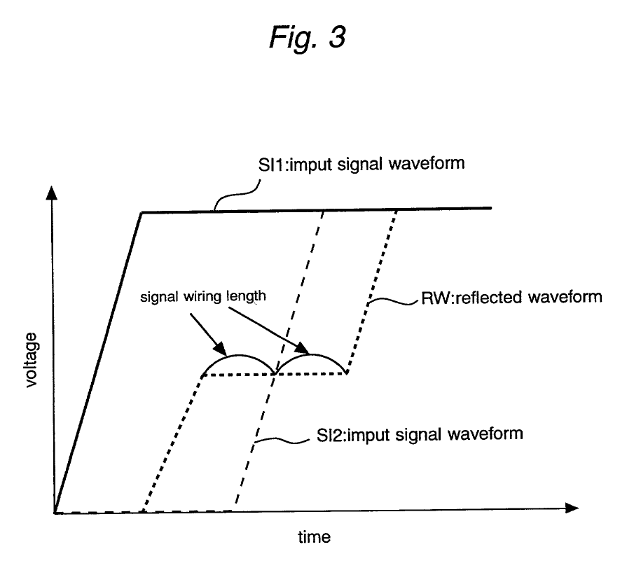

How signal wiring lengths are obtained by the TDR technique will now be described briefly with reference to FIG. 3.

A signal waveform entered from the pin electronics part 1a in FIG. 2 is assumed to be an input SI1. Without the IC 5 being mounted, the input SI1 is totally reflected by the probe 4a of the IC socket 4. When reaching half the voltage amplitude of the input SI1, the reflected waveform (indicated as RW) stays on a flat voltage level for a certain period of time.

The flat level period is twice the length of the signal wiring 3a, 3b in FIG. 2. Upon elapse of that period, the full voltage level of the input SI1 is reached. The probe 4a of the IC socket 4 in FIG. 2 is supplied with an input SI2 delayed by the electric length on the test board 3 with respect to the input SI1.

The time it takes the reflected waveform RW to reach a predetermined voltage level is measured, and the reflected waveform RW is observed at the pin electronics parts of the tester to find an electric length. Generally, three predetermined voltage levels are employed for the measurement.

Obviously, the obtained electric length varies depending on the signal line impedance and signal wiring length regarding different pins on the test board 3. Because the reflected waveform RW under observation is inferior in quality to the input SI2, errors are bound to be more pronounced. Once the IC 5 is mounted, the reflected waveform is not obtained normally because of impedance mismatch. This makes it impossible to acquire electric lengths, including the lengths up to pads of the semiconductor chip 6 in FIG. 2.

With the first embodiment, the semiconductor chip is arranged to incorporate terminating circuits, latch circuits, FIFO memories, and scan FF circuits allowing timing calibration up to pad ends of the chip. A high-speed clock generating circuit is mounted on the test board. Edges of waveforms generated by the clock generating circuit are used as a trigger signal for causing a measuring signal waveform to be captured from the tester. With the waveform thus admitted, timing skew values derived from different electric lengths at different pins are stored into the FIFO memories. Upon elapse of a predetermined period of time, the stored skew values are read into the tester via the scan FF circuits for calibration. Alternatively, the measuring signal waveform from the tester may be admitted by use of edges of a high-speed clock signal coming from the tester as a trigger signal.

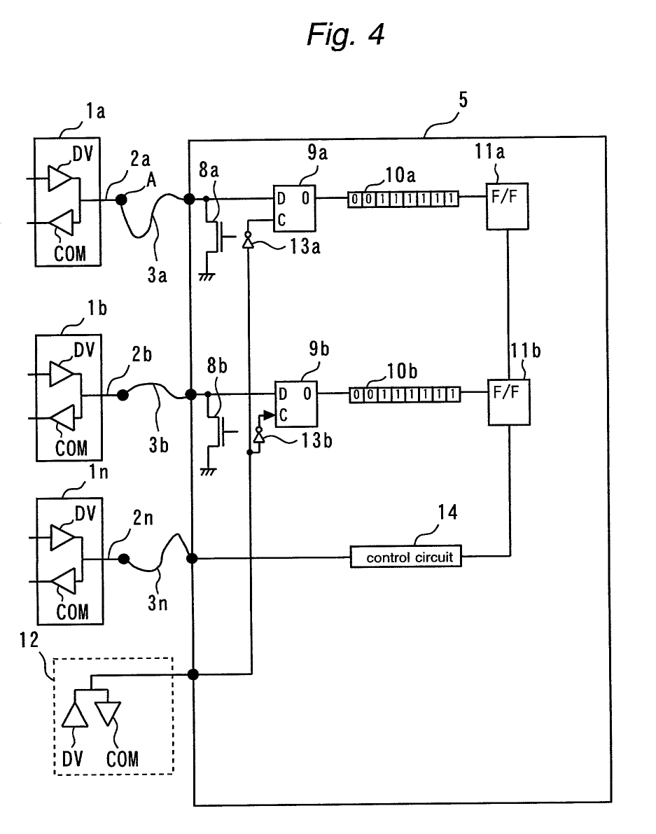

FIG. 4 is a block diagram of the first embodiment of this invention. In FIG. 4, the components having the same or corresponding functions as their counterparts in FIGS. 1 and 2 are designated by like reference numerals, and their descriptions are omitted where redundant.

In FIG. 4, reference numerals 1a, 1b, . . . 1n denote pin electronics parts of the tester; 2a, 2b, . . . 2n represent POGO pins; and 3a, 3b, . . . 3n stand for signal wiring on the test board. In this setup, the pin electronics parts 1a, 1b, etc., apply signal waveforms to the IC 5, and a pin electronics part 1c admits data from the IC 5. Reference numerals 8a, 8b stand for terminating circuits; 9a, 9b for latch circuits; 10a, 10b for memories (FIFO memories) for accommodating data latched by the latch circuits 9a, 9b; and 11a, 11b for scan FF circuits for reading data from the FIFO memories 10a, 10b respectively. The terminating circuits 8a, 8b and the latch circuits 9a, 9b constitute latching means, while the FIFO memories 10a, 10b and the scan FF circuits 11a, 11b make up storing means.

Reference numeral 12 denotes a high-speed clock generating circuit as clock generating means comprising a driver DV and a comparator COM for generating edges (trigger signal) by which to capture waveforms applied from the pin electronics parts 1a, 1b. The output of the high-speed clock generating circuit 12 is connected to clock terminals C of the latch circuits 9a, 9b via inverters 13a, 13b respectively. Reference numeral 14 represents a control circuit (JTAG circuit) for reading data from the scan FF circuits 11a, 11b. Alternatively, the high-speed clock generating circuit 12 may be replaced with the tester generating by itself a similar high-speed clock signal whose edges may be used to capture waveforms sent from the tester.

The terminating circuits 8a, 8b are furnished to ensure impedance matching with the pin electronics parts 1a, 1b of the tester. Since the pin electronics parts 1a, 1b usually have the output impedance of 50 ohms, the signal wiring 3a, 3b and the terminating circuits 8a, 8b are also fabricated with the output impedance of 50 ohms to ensure impedance matching. The terminating circuits 8a, 8b; latch circuits 9a, 9b; FIFO memories 10a, 10b; scan FF circuits 11a, 11b; high-speed clock generating circuit 12, and control circuit 14 constitute calibrating means for correcting the timing of measuring signal waveforms input to all pins of the IC 5.

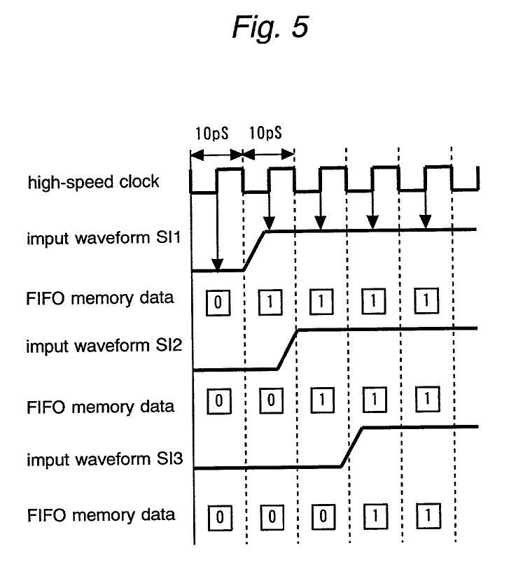

Automatic calibration will now be described by referring to FIG. 5 showing relevant timing waveforms.

A high-speed clock signal generated as a trigger signal by the high-speed clock generating circuit 12 is applied at intervals of 10 pS. If it is assumed that the waveform at point A in FIG. 4 occurs as a reflected waveform 2, the timing at that time is the same on all pins. The waveform having traveled the signal wiring on the test board to reach a package end of the IC 5 develops a skew of tens of pS, as shown in input waveforms SI1, SI2, SI3 in FIG. 5, due to differences in signal wiring lengths.

Using clock edges of the input SI1, the latch circuits 8a, 8b store digital data of 0's and 1's to the FIFO memories 10a, 10b at intervals of the high-speed clock waveform (i.e., in synchronism with its leading edges). The FIFO memories 10a, 10b should be provided beforehand with sufficient capacities to ensure the necessary resolution of timing accuracy.

The operation above causes skew values of the inputs SI1, SI2, SI3 to be placed into the FIFO memories 10a, 10b in the form of 0's and 1's.

The data thus stored are sent by the scan FF circuits 11a, 11b via the control circuit 14 to the outside (the tester in this example). The data fed to the tester are arranged into a calibration data file that takes a tabular form such as Table 1 below.

TABLE 1
Calibration Data File

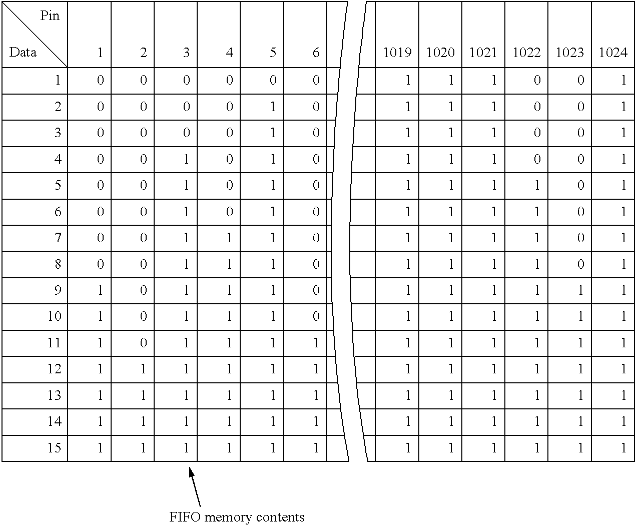

Where a functional test is to be performed, predetermined timing values for generating diverse waveforms are set on the pins involved. When the test is carried out, a calibration data file is referenced for calibration with respect to each pin.

In the calibration data file, each row in Table 1 above represents one unit cycle of the high-speed clock (10 pS in this example) so that highly accurate calibration is implemented. This setup realizes timing correction leading up to the pads of the semiconductor chip.

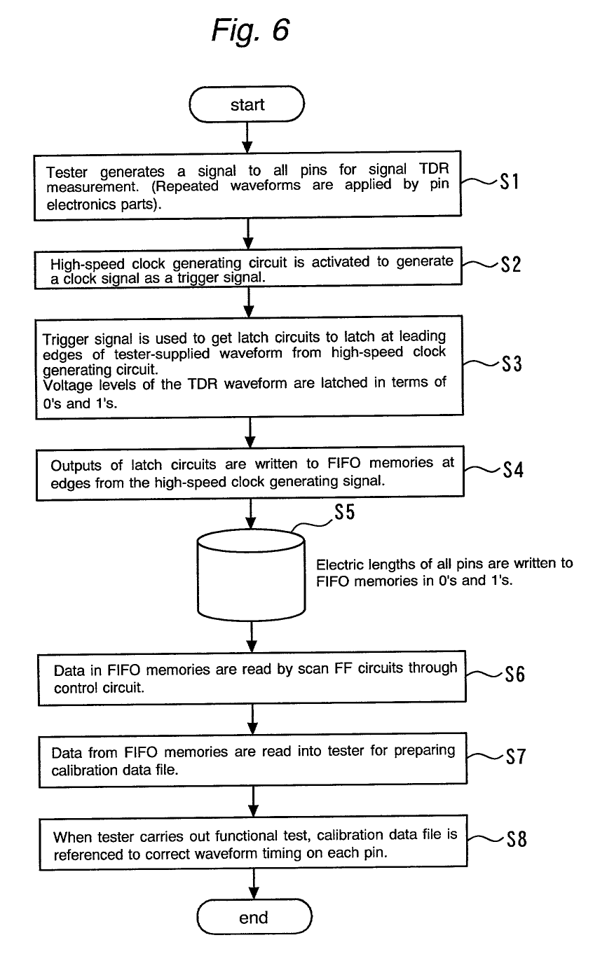

The technique for automatic calibration is outlined below by referring to FIG. 6.

Initially, the tester generates a signal for signal TDR measurement with regard to all pins. That is, a waveform is repeatedly applied by way of the pin electronics parts (step S1). The high-speed clock generating circuit 12 is activated to generate a clock signal as a trigger signal (step S2). The trigger signal thus generated is used to get the latch circuits 9a, 9b to latch the tester-supplied waveform at leading edges from the high-speed clock generating circuit 12. More specifically, the voltage levels of the TDR waveform are latched in terms of 0's and 1's (step S3).

The latched results are written to the FIFO memories 10a, 10b. That is, the outputs of the latch circuits 9a, 9b are written to the FIFO memories 10a, 10b at edges from the high-speed clock generating circuit 12 (step S4). Upon completion of a plurality of cycles of the high-speed clock, skew values at the pins are stored as data of 0's and 1's into the FIFO memories 10a, 10b. In other words, electric lengths of all pins are written to the FIFO memories 10a, 10b in the form of 0's and 1's (step S5).

The data held in the FIFO memories 10a, 10b are read therefrom by the scan FF circuits 11a, 11b through the control circuit 14 (step S6). The data thus retrieved from the FIFO memories 10a, 10b are read into the tester for use in preparing a calibration data file (step S7). When the tester generates various waveforms, this calibration data file is referenced for calibration with regard to each pin. That is, when the tester carries out a functional test, the calibration data file is referenced so as to correct the waveform timing on each pin (step S8).

With the first embodiment, as described, the skew values of timing stemming from different electric lengths of the pins involved are stored into the FIFO memories. The stored data are retrieved by the scan FF circuits upon elapse of a predetermined period of time and sent to the tester for calibration. This makes it possible to implement automated, highly accurate timing calibration in functional tests.

Second Errbodiment

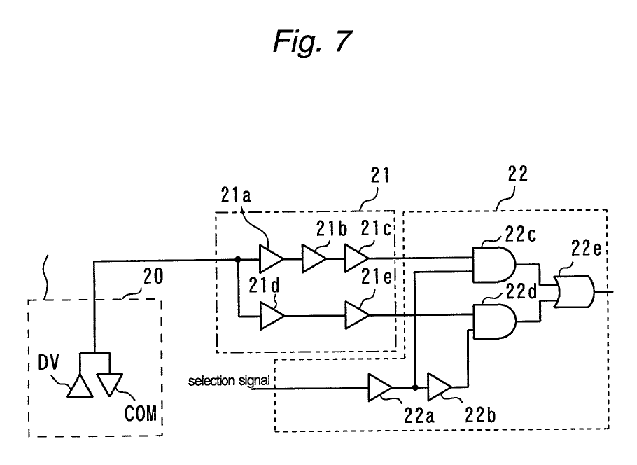

To further improve timing accuracy requires boosting the speed of the clock. Similar improvements are also obtained by adding a circuit such as shown in FIG. 7 to a low-speed clock generating circuit.

FIG. 7 sketches the second embodiment of this invention, comprising a delay circuit and a selection circuit furnished at the output end of a low-speed clock generating circuit. In FIG. 7, reference numeral 20 denotes a low-speed clock generating circuit including a driver DV and a comparator COM. Numeral 21 represents a delay circuit constituted by delay elements 21a through 21c connected in series and by serially connected delay elements 21d, 21e which in turn are connected parallelly to the delay element series 21a through 21c. The inputs of the delay elements 21a and 21d are connected in common to the output of the low-speed clock generating circuit 20. The delay elements 21a through 21c establish a first delay time, while the delay elements 21d and 21e set a second delay time.

Reference numeral 22 stands for a selection circuit for selecting either the first or the second delay time. The selection circuit 22 is illustratively constituted by serially connected delay element 22a, 22b; by an AND circuit 22c having two inputs, one connected to the output of the delay element 22a, the other to the output of the delay element 21c; by an AND circuit 22d with two inputs, one connected to the output of the delay element 22b, the other to the output of the delay element 21e; and by an OR circuit 22e having two inputs connected respectively to the outputs of the AND circuits 22d and 22c. The input of the delay element 22a receives a selection signal from the tester. The output of the OR circuit 22e, i.e., output of the selection circuit 22, is fed to the clock terminals C of the latch circuits 9a, 9b via the inverters 13a, 13b, as in the case of the output of the high-speed clock generating circuit 12 in FIG. 4. The low-speed clock generating circuit 20, delay circuit 21, and selection circuit 22 form clock generating means.

As described, the second embodiment comprises a delay circuit having two delay times. Alternatively, there may be provided a delay circuit offering more than two delay times depending on the low-speed clock frequencies and timing resolution requirements. When a clock waveform generated by the low-speed clock generating circuit 20 is arranged to pass through the delay circuit 21, that produces phase differences equivalent to delay times specific to the two delay paths, 21a through 21c on the one hand, and 22d and 22e on the other hand. One of the signals representing the delay times is selected by the selection circuit 22 based on the selection signal from the tester. The selected signal is fed to the latch circuits 9a, 9b.

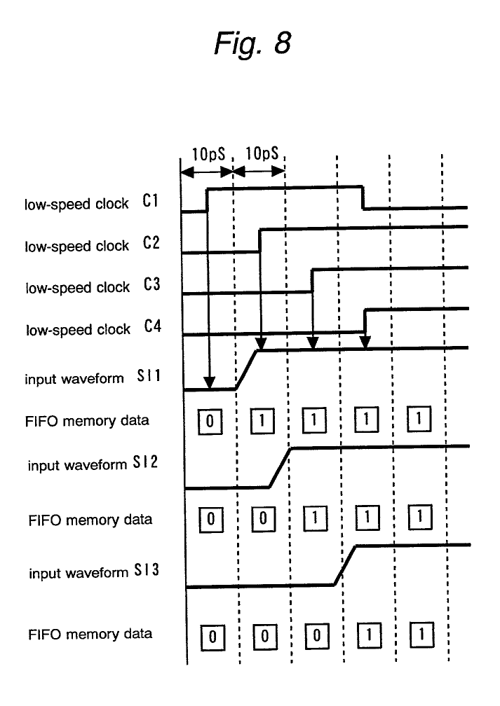

FIG. 8 is a timing chart in effect when the second embodiment of FIG. 7 is in operation. The chart shows low-speed clock signals C1 through C4 that have passed through the delay circuit 21. These clock signals permit delays of 10 pS each. A waveform of the input SI1 is first captured at an edge of the low-speed clock signal C1; the waveform is then captured likewise at an edge of the low-speed clock signal C2. The same holds for the low-speed clock signals C3 and C4, i.e., the waveform of the input SI1 is captured similarly at edges of these clock signals. The process is repeated with the inputs SI2 and SI3, and data of 0's and 1's are stored into the corresponding FIFO memories 10a, 10b, 10c.

As with the first embodiment, the stored data are read by the scan FF circuits 11a, 11b via the control circuit 14 and sent to the outside (tester in this example). The retrieved data are arranged into a calibration data file in tabular form such as Table 1 shown earlier.

As described, the second embodiment permits highly accurate timing calibration using a tester operating at low basic frequencies with low degrees of timing precision.

In the above-described high-speed and low-speed clock generating circuits, the driver DV and comparator COM may be replaced by a self-oscillator.

The features and major benefits of this invention are summarized as follows:

According to a first aspect of the invention, as claimed in claim 1, there is provided a semiconductor integrated circuit testing method comprising the steps of: causing a tester to generate a measuring signal to all pins of a semiconductor integrated circuit; generating a trigger signal; latching the measuring signal by use of the trigger signal; storing the latched measuring signal as data into storing means; and reading the stored data from the storing means for output to the tester. This method permits highly accurate timing correction enabling automatic calibration of high-precision timing in functional tests.

In one variation of the invention according to the first aspect thereof, as claimed in claim 2, the data stored into the storing means represent electric lengths of all pins of the semiconductor integrated circuit. This feature contributes to implementing automatic calibration of high-precision timing in functional tests.

In another variation according to the first aspect of the invention, as claimed in claim 3, the semiconductor integrated circuit testing method further comprises the step of creating a calibration data file based on the data sent to the tester. This feature also contributes to implementing automatic calibration of high-precision timing in functional tests.

In a further variation according to the first aspect of the invention, as claimed in claim 4, the semiconductor integrated circuit testing method further comprises the step of referencing the calibration data file to correct waveform timing of the measuring signal upon functional test performed by the tester. This feature makes it possible efficiently to carry out automatic calibration of high-precision timing.

In an even further variation according to the first aspect of the invention, as claimed in claim 5, the trigger signal is a high-speed clock signal. This feature contributes to implementing automatic calibration of high-precision timing in functional tests.

In a still further variation according to the first aspect of the invention, as claimed in claim 6, the trigger signal is selected from among a plurality of signals generated with different delay times on the basis of a low-speed clock signal. This feature permits highly accurate timing calibration even with a tester having a low level of timing accuracy.

According to a second aspect of the invention, as claimed in claim 7, there is provided a semiconductor integrated circuit testing apparatus comprising correcting means for correcting input waveform timing of a measuring signal applied to all pins of a semiconductor integrated circuit. This apparatus permits highly accurate timing correction enabling automatic calibration of high-precision timing in functional tests.

In one preferred structure of the invention according to the first aspect thereof, as claimed in claim 8, the correcting means includes: clock generating means for generating a clock signal; latching means for latching the measuring signal by use of the clock signal from the clock generating means; storing means for storing as data the measuring signal latched by the latching means; and controlling means for retrieving the data held in the storing means for output to an external entity. This structure contributes to implementing automatic calibration of high-precision timing in functional tests.

In another preferred structure according to the second aspect of the invention, as claimed in claim 9, the latching means, the storing means and the controlling means are incorporated in the semiconductor integrated circuit. This structure contributes to making the apparatus smaller in size and less costly to fabricate.

In a further preferred structure according to the second aspect of the invention, as claimed in claim 10, the latching means is constituted by terminating circuits and latch circuits, and the storing means by FIFO memories and scan FF circuits. This structure makes it possible efficiently to carry out automatic calibration of high-precision timing.

In an even further preferred structure according to the second aspect of the invention, as claimed in claim 11, the clock generating means is a high-speed clock generating circuit for generating a high-speed clock signal. This structure contributes to implementing automatic calibration of high-precision timing in functional tests.

In a still further preferred structure according to the second aspect of the invention, as claimed in claim 12, the clock generating means includes: a low-speed clock generating circuit for generating a low-speed clock signal; a delay circuit for generating a plurality of signals with different delay times on the basis of the output from the low-speed clock generating circuit; and a selection circuit for selecting one of the plurality of signals from the delay circuit. This structure permits highly accurate timing calibration even with a tester having a low level of timing accuracy.

According to a third aspect of the invention, as claimed in claim 13, a semiconductor integrated circuit is fabricated by use of a semiconductor integrated circuit testing method according to any one of claims 1 through 6. Fabricating semiconductor integrated circuits by use of the inventive testing method provides a good yield rate and high product quality.

According to a fourth aspect of the invention, as claimed in claim 14, a semiconductor integrated circuit is fabricated by use of a semiconductor integrated circuit testing apparatus according to any one of claims 7 through 12. Fabricating semiconductor integrated circuits by use of the inventive testing apparatus promises an excellent yield rate and enhanced product quality.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2000-216321, filed on Jul. 17, 2000 including specification, claims, drawings and summary, on which the Convention priority of the present application is based, are incorporated herein by reference in its entirety.

What is claimed is:

1. A semiconductor integrated circuit testing method comprising the steps of:
causing a tester to generate a measuring signal to all pins of a semiconductor integrated circuit;
generating a trigger signal;
latching said measuring signal by use of said trigger signal;
storing the latched measuring signal as data into storing means; and
reading the stored data from said storing means for output to said tester.

2. The semiconductor integrated circuit testing method according to claim 1, wherein the data stored into said storing means represent electric lengths of all pins of said semiconductor integrated circuit.

3. The semiconductor integrated circuit testing method according to claim 1, further comprising the step of creating a calibration data file based on the data sent to said tester.

4. The semiconductor integrated circuit testing method according to claim 3, further comprising the step of referencing said calibration data file to correct waveform timing of said measuring signal upon functional test performed by said tester.

5. The semiconductor integrated circuit testing method according to claim 1, wherein said trigger signal is a high-speed clock signal.

6. The semiconductor integrated circuit testing method according to claim 1, wherein said trigger signal is selected from among a plurality of signals generated with different delay times on the basis of a low-speed clock signal.

7. A semiconductor integrated circuit testing apparatus comprising correcting means for correcting input waveform timing of a measuring signal applied to all pins of a semiconductor integrated circuit.

8. The semiconductor integrated circuit testing apparatus according to claim 7, wherein said correcting means includes:
clock generating means for generating a clock signal;
latching means for latching said measuring signal by use of said clock signal from said clock generating means;
storing means for storing as data said measuring signal latched by said latching means; and
controlling means for retrieving the data held in said storing means for output to an external entity.

9. The semiconductor integrated circuit testing apparatus according to claim 8, wherein said latching means, said storing means and said controlling means are incorporated in said semiconductor integrated circuit.

10. The semiconductor integrated circuit testing apparatus according to claim 8, wherein said latching means is constituted by terminating circuits and latch circuits, and said storing means by FIFO memories and scan FF circuits.

11. The semiconductor integrated circuit testing apparatus according to claim 8, wherein said clock generating means is a high-speed clock generating circuit for generating a high-speed clock signal.

12. The semiconductor integrated circuit testing apparatus according to claim 8, wherein said clock generating means includes:
a low-speed clock generating circuit for generating a low-speed clock signal;
a delay circuit for generating a plurality of signals with different delay times on the basis of the output from said low-speed clock generating circuit; and
a selection circuit for selecting one of said plurality of signals from said delay circuit.

13. The semiconductor integrated circuit fabricated by use of a semiconductor integrated circuit testing method according to claim 1.

14. The semiconductor integrated circuit fabricated by use of a semiconductor integrated circuit testing apparatus according to claim 7.
